(19) United States
(12) Patent Application Publication
(10) Pub. No.: US 2020/0019220 A1
(43) Pub. Date: Jan. 16, 2020

(54) POWER DISTRIBUTION UNIT AND SETTING METHOD THEREOF

(71) Applicant: Digipower Manufacturing Inc., New Taipei City (TW)

(72) Inventor: Min-Huang Huang, New Taipei City (TW)

(73) Assignee: Digipower Manufacturing Inc., New Taipei City (TW)

(21) Appl. No.: 16/221,622

(22) Filed: Dec. 17, 2018

(30) Foreign Application Priority Data
Jul. 10, 2018 (TW) 107123825

(51) Int. Cl. G06F 1/18; H03K 19/00; G06F 1/3234

(52) U.S. Cl. CPC G06F 1/189; G06F 1/3234; H03K 19/0016

(57) ABSTRACT

A power distribution unit (PDU) and a setting method thereof are provided. The PDU includes a signal input port, a power output port and an embedded system. The embedded system is coupled to the signal input port and the power output port and configured to provide a setting interface. The setting interface is configured to set a current provided by the power output port and a corresponding logic value combination of a plurality of signals received by the signal input port, so as to generate an output rule of the PDU. In response to a plurality of input signals received by the signal input port, the embedded system controls an output of the power output port according to a logic value combination of the received input signal and the set output rule.

### CROSS-REFERENCE TO RELATED APPLICATION

This application claims the priority benefit of Taiwan patent application serial no. 107123825, filed on Jul. 10, 2018. The entirety of the above-mentioned patent application is hereby incorporated by reference herein and made a part of the specification.

### BACKGROUND

### Field of the Invention

The invention relates to a power distribution unit (PDU) and more particularly, to a smart PDU in which an input and an output can be logically set and a setting method thereof.

### Description of Related Art

A power distribution unit (PDU) is a device which distributes power for various electronic apparatuses. The PDU commonly seen in a computer room or a data center is, for example, a rack PDU capable of managing power for computer apparatuses in the computer room, including digitally integrating power switches, bus plugs, wire currents, loops and power distribution and so on.

Thus, how to provide a convenient method for the setting of the power management to achieve easy management, save power consumption and save human resource management cost is a goal for the technicians of this field to dedicate themselves to.

### SUMMARY

Accordingly, the invention provides a power distribution unit (PDU) and a setting method thereof, which can provide a setting interface that is easy to understand and convenient to use.

A PDU provided by the invention includes a signal input port, a power output port and an embedded system. The signal input port is configured to receive a plurality of signals. The power output port is configured to provide a current. The embedded system is coupled to the signal input port and the power output port and configured to provide a setting interface. The setting interface is configured to set the current provided by the power output port and a corresponding logic value combination of the plurality of signals received by the signal input port, so as to generate an output rule of the PDU. In response to a plurality of input signals received by the signal input port, the embedded system controls an output of the power output port according to a logic value combination of the received input signals and the set output rule.

In an embodiment of the invention, the power PDU further includes a communication interface. The communication interface is coupled to the embedded system and configured to connect to an Ethernet. The embedded system provides the setting interface through the Ethernet and receives an external set signal through the Ethernet, so as to generate the output rule according to the external set signal.

In an embodiment of the invention, the embedded system provides the setting interface on a web page, and the web page is connected by an external device through the Ethernet for accessing the setting interface and providing the external set signal.

In an embodiment of the invention, the embedded system is configured to set a current threshold and determine the logic value combination of the input signals according to the input signals and the current threshold.

In an embodiment of the invention, the setting interface is further configured to set a timer, and the embedded system controls the output of the power output port according to the timer.

A setting method provided by the invention is applicable to a power distribution unit (PDU) including a signal input port, a power output port and an embedded system and includes the following steps. A setting interface is provided by the embedded system, wherein the setting interface is configured to set a current provided by the power output port and a corresponding logic value combination of a plurality of signals received by the signal input port, so as to generate an output rule of the PDU. In response to a plurality of input signals received by the signal input port, an output of the power output port is controlled according to a logic value combination of the received input signal and the set output rule by the embedded system.

In an embodiment of the invention, the setting interface is provided by the embedded system through an Ethernet, and the setting method further the following step. By the embedded system, an external set signal is received by the embedded system through the Ethernet, so as to generate the output rule according to the external set signal.

In an embodiment of the invention, the setting interface is provided on a web page, and the web page is connected by an external device through the Ethernet for accessing the setting interface and providing the external set signal.

In an embodiment of the invention, the setting method further the following steps. A current threshold is set. The logic value combination of the input signals is determined according to the input signals and the current threshold.

In an embodiment of the invention, the setting interface is further configured to set a timer, wherein the output of the power output port is controlled according to the timer by the embedded system.

To sum up, the PDU and the setting method thereof provided by the embodiments of the invention can provide the setting interface that is easy to understand, such that a user can set the output rule of the PDU by means of setting logic values. In some embodiments of the invention, the setting interface is further provided in a form of web page for the user to connect to the web page through the Ethernet to access the setting interface, so as to set the output rule of the PDU to improve conveniences of power management.

To make the above features and advantages of the invention more comprehensible, embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic block view showing a power distribution unit (PDU) according to an embodiment of the invention.

FIG. 2 is a schematic device view showing the PDU on two opposite sides according to an embodiment of the invention.

FIG. 3 is a schematic view showing a setting method of the PDU according to an embodiment of the invention.

FIG. 4 is a schematic view showing the setting interface according to an embodiment of the invention.

### DESCRIPTION OF EMBODIMENTS

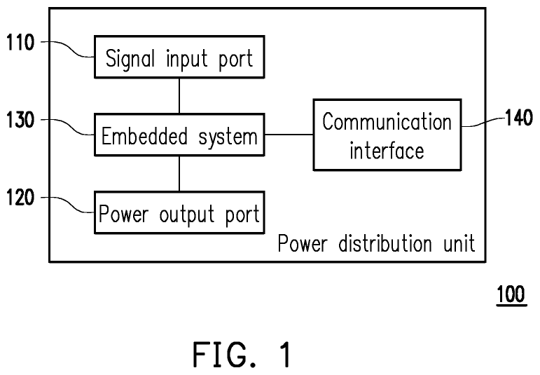

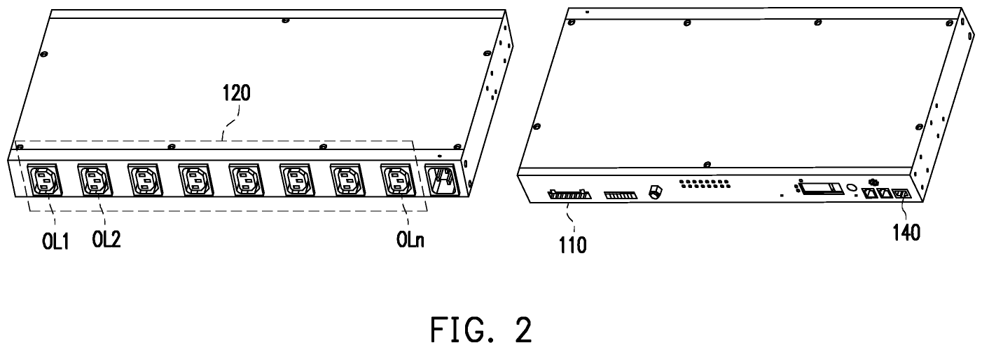

FIG. 1 is a schematic block view showing a power distribution unit (PDU) according to an embodiment of the invention. FIG. 2 is a schematic device view showing the PDU on two opposite sides according to an embodiment of the invention.

Referring to FIG. 1 and FIG. 2, a PDU 100 includes a signal input port 110, a power output port 120, an embedded system 130 and a communication interface 140. The embedded system 130 is coupled to the signal input port 110, the power output port 120 and the communication interface 140, respectively. As illustrated in FIG. 2, the embedded system 130 of the PDU 100 is enclosed in a housing, and a plurality of openings are provided on the housing for the disposition of the signal input port 110, the power output port 120 and the communication interface 140.

The signal input port 110 includes a plurality of input terminals respectively configured to receive signals. In some embodiments, the signal input port 110 is connected to, for example, a temperature sensor, a humidity sensor, an access control system or other devices and configured to receive signals from the connected device, but the invention is not limited thereto. For example, in the signal input port 110, the input terminals connected to the temperature sensor are employed to receive temperature sensing signals, the input terminals connected to the humidity sensor are employed to receive humidity sensing signals, the input terminals connected to the access control system are employed to receive identity authentication signals and so on. However, the type of the signals received by the signal input port 110 is not limited in the invention. In some embodiments, the signal input port 110 is configured to receive digital signals, in some embodiments, the signal input port 110 is configured to receive analog signals, and in some embodiments, each of the input terminals of the signal input port 110 is configured to receive digital signals or analog signals.

The power output port 120 includes at least one outlet OL1 to OLn respectively configured to provide a current. In some embodiments, the power output port 120 is connected to, for example, a computer system, an access control system, an air condition system and so on and configured to output the current to the connected device, but the invention is not limited thereto. For example, the power output port 120 may control the current output from each of the outlets OL1 to OLn, so as to turn on, turn off or adjust the power provided to the connected device, thereby, for example, turning on or off a computer or a door lock, or adjusting the air condition.

The embedded system 130 is configured to provide a setting interface for setting an output rule of each of the outlets of the PUD 100. In some embodiments, the embedded system 130 is, for example, a central processing unit (CPU) or any other programmable microprocessor for general or special use, a digital signal processor (DSP), a programmable controller, an application specific integrated circuit (ASIC), a programmable logic device (PLD) or other similar devices, or implemented by a combination of these devices, which are not limited in the invention.

The communication interface 140 is coupled an Ethernet in a wired or a wireless manner. In some embodiments, the communication interface 140 may be, for example, a wireless network module for accessing to the Internet in a wireless manner, or include an Ethernet interface connected to the Ethernet in a wired manner, but the invention is not limited thereto.

In some embodiments, an external device may be connected to a web page including the setting interface which is provided by the embedded system 130, so as to set the output rule of each of the outlets of the PUD 100. An example will be provided below to describe a setting method of the PDU 100 provided by the embodiments of the invention.

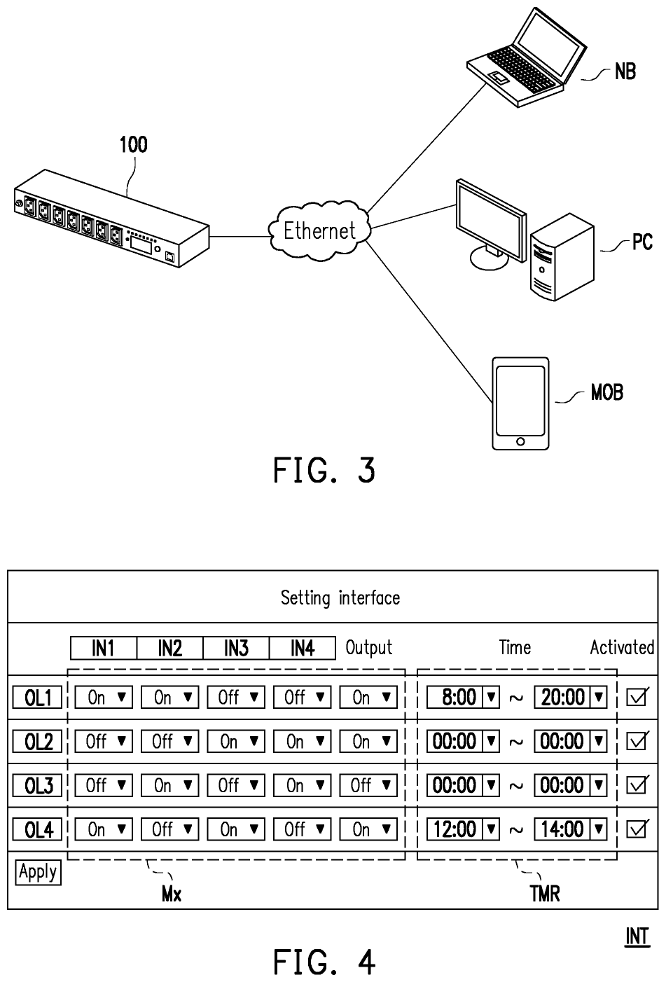

FIG. 3 is a schematic view showing a setting method of the PDU according to an embodiment of the invention.

Referring to FIG. 3, the embedded system 130 of the PUD 100 is connected to the Ethernet through the communication interface 140 and provides the setting interface in a form of web page. The setting interface is configured to set the current and a corresponding logic value combination of the signals, so as to generate the output rule of the PDU. On the other hand, a user may connect to the web page provided by the embedded system 130 with a notebook computer NB, a personal computer PC, a smart mobile phone MOB or other similar devices through the Ethernet, so as to access the setting interface and provide an external set signal to set the setting interface. However, as long as the external device is capable of being connected to the web page provided by the embedded system 130 to access the setting interface, the type of the external device as used is not limited in the invention.

In some embodiments, the setting interface is designed in a pattern of a logic matrix, for example. Each row in the logic matrix is configured to set an output rule of one outlet and includes a plurality of entries configured to set the logic value combination of the signals received by the signal input port 110 and an output logic value provided by the outlet. An embodiment will be provided below to introduce the setting interface. However, the setting interface of the invention is not limited to the embodiment described below, and those with ordinary skills in the art can design the setting interface based on requirements thereof.

FIG. 4 is a schematic view showing the setting interface according to an embodiment of the invention.

Referring to FIG. 4, in some embodiments, a setting interface INT including a 4×5 logic matrix Mx is configured to set output rules of four outlets OL1 to OL4 of the power output port 120. As illustrated in FIG. 4, the first row of the logic matrix Mx is configured to set the output rule of the outlet OL1, includes four entries configured to set logic values of signals from four input terminals IN1 to IN4 of the signal input port 110 and includes a last entry configured to set an output logic value of the outlet OL1. The second row of the logic matrix Mx is configured to set the output rule of the outlet OL2, includes four entries configured to set the logic values of the signals from the four input terminals IN1 to IN4 of the signal input port 110 and includes the last entry configured to set an output logic value of the outlet OL2. The others are so deduced by analog. The logic values of the signals and the output logic values may be represented by ON (e.g., a logic value of 1) and OFF (e.g., a logic value of 0). It is to be mentioned that although the setting interface INT of the embodiment illustrated in FIG. 4 is exemplified by four input terminals and four outlets, the numbers of the input terminals and the outlets are not limited in the invention.

The user may connect to the web page provide by the embedded system 130 to access the setting interface INT through the Ethernet, for example, by using the external device and set the value of each of the entries of the logic matrix Mx in the setting interface INT, so as to generate an external set signal and provide them to the embedded system 130, while the embedded system 130 may receive the external set signal and accordingly generate the output rule of the PUD 100 according to the external set signal.

To be detailed, the first row of the logic matrix Mx is configured to set the output rule of the outlet OL1, wherein the five entries thereof are respectively set to (1, 1, 0, 0, 1), which represents that when the logic value combination of the plurality of signals received by the input terminals IN1 to IN4 of the signal input port 110 is (1, 1, 0, 0), the outlet OL1 is turned on according to the logic value of 1 and provides the current. The second row of the logic matrix Mx is configured to set the output rule of the outlet OL2, wherein the five entries thereof are respectively set to (0, 0, 1, 1, 1), which represents that when the logic value combination of the signals received by the input terminals IN1 to IN4 of the signal input port 110 is (0, 0, 1, 1), the outlet OL2 is turned on according to the logic value of 1 and provides the current. The third row of the logic matrix Mx is configured to set the output rule of the outlet OL3, wherein the five entries thereof are respectively set to (0, 1, 0, 1, 0), which represents that when the logic value combination of the signals received by the input terminals IN1 to IN4 of the signal input port 110 is (0, 1, 0, 1), the outlet OL3 is turned off according to the logic value of 0 and stops providing the current. The fourth row of the logic matrix Mx is configured to set the output rule of the outlet OL4, wherein the five entries thereof are respectively set to (1, 0, 1, 0, 1), which represents that when the logic value combination of the signals received by the input terminals IN1 to IN4 of the signal input port 110 is (1, 0, 1, 0), the outlet OL4 is turned on according to the logic value of 1 and provides the current.

In this way, when the input signals are received by the signal input port 110, the embedded system 130 may control the output of the power output port 120 according to the logic value combination of the received input signals and the set output rule. Taking the output rule set in FIG. 4 for example, the embedded system 130 determines for each row of the logic matrix Mx whether the former four entries match the logic value combination of the four input signals and controls an output current of the corresponding outlet in the power output port 120 according to the last entry of the row that matches the logic value combination. In some embodiments, when none of the former four entries of each row of the logic matrix Mx match the logic value combination of the four input signals, the power output port 120 maintain the current state of the output without switching or changing.

In some embodiments, the signal input port 110, for example, receives signals (for example, but not limited to analog signals) except for binary logic signals, and the embedded system 130, for example, sets a current threshold and decides the logic values of the input signals according to the current sizes of the input signals and the current threshold. For example, the embedded system 130 sets, for example, a first current threshold for the input terminal connected to the temperature sensor and when the input terminal connected to the temperature sensor receives a current which is greater than the first current threshold, determines the logic value of the input signal corresponding to this input terminal as 1, otherwise, determines the logic value of the input signal corresponding to this input terminal as 0. For another example, the embedded system 130 sets, for example, a second current threshold for the input terminal connected to the humidity sensor and when the input terminal connected to the temperature sensor receives a current which is greater than the second current threshold, determines the logic value of the input signal corresponding to this input terminal as 1, otherwise, determines the logic value of the input signal corresponding to this input terminal as 0.

It is to be mentioned that specific means of the embedded system 130 converting the signals received by the signal input port 110 into the logic values is not limited in the invention, and those with ordinary skills in the art may design it based on requirements. Accordingly, no matter which types of the signals received by the input terminal 110 are, the embedded system 130 may convert the signals into the logic values and control the output of the power output port 120 according to the set output rules.

In some embodiments, the setting interface INT may be further configured to set a timer TMR. For instance, the timer TMR may be set corresponding to each of the outlets OL1 to OL4, so as to set a time period for each of the outlets OL1 to OL4 being turned on or turned off according to the input terminals IN1 to IN4. As illustrated in FIG. 4, the timer TMR corresponding to the outlet OL1 is set to a time period from 08:00 to 20:00. It represents that only when the logic value combination of the signals received by the input terminals IN1 to IN4 of the signal input port 110 in the time period from 8:00 to 20:00 presents (1, 1, 0, 0), the outlet OL1 is turned on according to the logic value of 1 and provides the current. The timer TMR corresponding to the outlet OL2 is set to a time period from 00:00 to 00:00. It represents that the timer TMR does not limit the time, namely, once the logic value combination of the signals received by the input terminals IN1 to IN4 of the signal input port 110 is (0, 0, 1, 1), the outlet OL2 is turned on according to the logic value of 1 and provides the current. The others may be so deduced by analog. After the setting is completed, the embedded system 130 may control the output of each of the outlets OL1 to OL4 of the power output port 120 according to the timer TMR which is set in the setting interface INT.

Based on the above, the PDU and the setting method provided by the embodiments of the invention can provide the setting interface that is easy to understand, such that the user can set the output rule of the PUD by means of setting the logic values. In some embodiments of the invention, the setting interface is further provided in a form of web page for the user to connect to the web page through the Ethernet to access the setting interface, so as to set the output rule of the PDU to improve conveniences of power management.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A power distribution unit, comprising:
a signal input port, configured to receive a plurality of signals;
a power output port, configured to provide a current; and
an embedded system, coupled to the signal input port and the power output port and configured to:
provide a setting interface, wherein the setting interface is configured to set the current provided by the power output port and a corresponding logic value combination of the plurality of signals, so as to generate an output rule of the power distribution unit,
wherein in response to a plurality of input signals received by the signal input port, the embedded system controls an output of the power output port according to a logic value combination of the received input signals and the set output rule.

2. The power distribution unit according to claim 1, further comprising:
a communication interface, coupled to the embedded system and configured to connect to an Ethernet, wherein the embedded system provides the setting interface through the Ethernet,
wherein the embedded system receives an external set signal through the Ethernet, so as to generate the output rule according to the external set signal.

3. The power distribution unit according to claim 2, wherein the embedded system provides the setting interface on a web page, and the web page is connected by an external device through the Ethernet for accessing the setting interface and providing the external set signal.

4. The power distribution unit according to claim 1, wherein the embedded system is configured to:
set a current threshold; and
determine the logic value combination of the input signals according to the input signals and the current threshold.

5. The power distribution unit according to claim 1, wherein the setting interface is further configured to set a timer, and the embedded system controls the output of the power output port according to the timer.

6. A setting method of a power distribution unit comprising a signal input port, a power output port and an embedded system, comprising:
providing a setting interface by the embedded system, wherein the setting interface is configured to set a current provided by the power output port and a corresponding logic value combination of a plurality of signals received by the signal input port, so as to generate an output rule of the power distribution unit;
in response to a plurality of input signals received by the signal input port, controlling an output of the power output port according to a logic value combination of the received input signal and the set output rule by the embedded system.

7. The setting method according to claim 6, wherein the embedded system provides the setting interface through an Ethernet, and the setting method further comprises:
by the embedded system, receiving an external set signal through the Ethernet, so as to generate the output rule according to the external set signal.

8. The setting method according to claim 7, wherein the setting interface is provided on a web page, and the web page is connected by an external device through the Ethernet for accessing the setting interface and providing the external set signal.

9. The setting method according to claim 6, further comprising:
setting a current threshold; and
determining the logic value combination of the input signals according to the input signals and the current threshold.

10. The setting method according to claim 6, further comprising:
setting a timer, wherein the output of the power output port is controlled according to the timer by the embedded system.
